(19) United States
(12) Patent Application Publication
(10) Pub. No.: US 2006/0045677 A1
(43) Pub. Date: Mar. 2, 2006

(54) Loading and unloading device

(76) Inventors: Steven M. Garfield, University Heights, OH (US); Laura G. Gordos, Euclid, OH (US)

Correspondence Address: D.A. STAUFFER PATENT SERVICES LLC, 1006 MONTFORD ROAD, CLEVLAND HTS., OH, 44121-2016, US

(21) Appl. No.: 11/212,379

(22) Filed: Aug. 26, 2005

Related U.S. Application Data
(60) Provisional application No. 60/604,816, filed on Aug. 26, 2004.

(51) Int. Cl. B65F 9/00; B60P 9/00; H01L 21/677

(52) U.S. Cl. 414/340; 414/462; 414/800

(57) ABSTRACT

A loading and unloading device is disclosed in the form of an independent rail lift that may also be built into a loadable object. The device collapses for storage and handling, and telescopes to make a ramp with a motorized carriage. Two parallel telescoping slide rails are spaced apart by a ground resting foot and a hook shaped handle. The motor operates on a cog rail to drive the carriage as a lift that slides on a ramp formed by leaning the slide rails against a platform that is raised above the ground. Preferably the rail lift is used to lift luggage up to, or down from, a platform that may be a passenger vehicle trunk, a bed, a luggage stand, etc., advantageously by being built into the luggage. Wheels can be added to allow object portage by functioning as a dolly.

### CROSS-REFERENCE TO RELATED APPLICATIONS

This application claims the benefit of U.S. Provisional Patent Application No. 60/604,816, filed Aug. 26, 2004 by Garfield, et al., and incorporated by reference in its entirety herein.

### TECHNICAL FIELD OF THE INVENTION

The present invention relates to combined transport and loading/unloading devices for objects to be loaded in vehicles and, more particularly, to personal luggage transport, loading and unloading devices for passenger vehicle trunks and, most particularly, for said devices that are compactly collapsible, portable, and storable.

### BACKGROUND OF THE INVENTION

Various types of portable luggage carriers are in use, for example, the two-wheeled dolly type onto which luggage is strapped and wheeled from place to place. When the dolly reaches its destination, the luggage is unstrapped and carried to and placed in or on, for example, an automobile trunk, a station wagon/SUV/van trunk, or a pickup truck bed. Similarly, collapsible two-wheel dollies are widely used, either built into an item of luggage (with an extendable handle), or separate but suitable for airline carryon use. In addition, there are four-wheeled luggage carriers such as the low dolly used by porters at airports, train stations and bus stations, or such as shopping cart-like carriers that are available for personal use by travelers. All of these can be used to carry luggage to and from a vehicle, but none of the typical luggage carriers provide a means as part of the carrier to mechanically lift the luggage to enable it to be placed at a desired location or into a storage area such as an automobile trunk. Such a luggage carrier would make it easier for persons to, for example: load and unload luggage into and out of an vehicle trunk or truck bed; place such luggage on or take it off an elevated platform such as a loading dock or a bed or rack or table for packing and unpacking; or even to place the luggage in a storage locker and take it out. A luggage carrier with loading and unloading capability would be especially useful for persons without sufficient strength to easily lift the luggage, such as certain elderly persons, children or handicapped persons. This is particularly true for large, heavy luggage such as a 70 pound suitcase or bag as is permitted on many airlines. Of course, such a carrier would not have to be limited to luggage, but could also be used to load and unload moderately heavy and/or awkward objects of many different kinds, for example: boxes, a bag of dirt, a bundle of shingles, and so on. Furthermore, as noted, the object could be loaded and unloaded to/from many types of raised platforms, not just vehicles.

Thus there is a need for a compactly collapsible, portable and storable device that not only transports but also assists with lifting luggage both into and out of vehicles. As mentioned hereinabove, such a device can also be put to many other uses, thereby increasing its value.

The prior art includes various attempts to meet this need, but they all have limitations: some being too bulky and awkward to be readily portable with luggage, and many others being limited to use with a specific vehicle, thus lacking portability and luggage transport capability.

U.S. Pat. No. 5,195,726 (Kaner; 1993), discloses a portable luggage carrier that has means to lift luggage thereon onto a desired location and to return luggage from the desired location to the luggage carrier, the desired location being, for example, an automobile trunk. The carrier is foldable for ease of carrying and/or storing and can also be disassembled into two parts, if needed, for carrying and/or storing. Optionally, the carrier can have straps for holding down the luggage thereon. A preferred means for lifting the luggage is a hand cranked winch for raising and lowering a hook on the end of a rope. When in use, the hook is attached to the luggage handle for lifting and/or lowering. The winch can also be powered by a battery operated motor containing its own batteries or it can be plugged into an automobile cigarette lighter for power. The carrier comprises a generally rectangular platform having four wheels, and an upright handle structure adapted to support a winch and pulley means foldably attached substantially perpendicularly to the platform on the rear top portion thereof for pushing, pulling and steering the carrier.

U.S. Pat. No. 6,024,527 (Soriano; 2000) discloses a shopping cart, loadable full and effortlessly into a car trunk that comprises a cart with a removable basket and a four wheeled rolling support. As illustrated in his FIGS. 6-13, 18 and 19, the basket is mechanically lifted in or out of the trunk, and the rolling support is collapsed and placed in the car trunk around the basket when it is disconnected from rolling legs and basket supporting arms. The basket is movable with respect to the support and rotated by rods which form two deformable parallelograms. An electric or crank control transmits the synchronous motion to two reduction units located on either side of the basket.

U.S. Pat. No. 4,604,022 (Bourgraf; 1986) discloses a trunk loading device for business machines and the like comprising a lifting mechanism adapted to be placed in the trunk of a vehicle, the lifting mechanism having a lift platform movable from a storage position within the trunk to an elevated position in which the lift platform projects outwardly from the trunk, the platform being raised and lowered by a lever mechanism with or without a powered assist. The lifting mechanism may be used alone or in combination with a wheeled cart and an article supporting carriage by means of which the article may be transferred between the cart and the lifting mechanism (FIG. 6).

A variety of prior art documents disclose vehicle loading aids that are specific to a given vehicle and which do not provide for transport of the loaded objects.

German Patent DE 4,229,762 (Hoppe, et al.; 1993) discloses a loading aid for a vehicle roof rack having hinged sliding bars which move pallets along horizontal carrier beams. The pallets are manually pushed up the ramped carrier beams, carrying, for example, a number of bicycles to be loaded on the roof rack.

U.S. Pat. No. 4,858,981 (Post; 1989) discloses a vehicle loading attachment comprising an attachment and method to implement loading of a vehicle having a hinged storage compartment closure member such as a trunk lid or hatchback on an automobile by utilizing the closure member as a lifting lever. The conventional hinged trunk lid or hatchback is formed with one or more hook or other material engaging members at the free end of the lid or hatchback and a piston-cylinder assembly is positioned between the vehicle body and the lid or hatchback, and fluid from a fluid system is selectively directed to the variable charge fluid chamber in the cylinder to displace the piston against the trunk or hatchback lid to lift same, whereby any material engaged by the hook can be lifted to a position over the vehicle storage compartment.

U.S. Pat. No. 4,073,395 (Clement; 1978) discloses an automobile trunk loading apparatus for loading wheelchairs, outboard motors and the like into the trunk of an automobile, that comprises a carrier frame on which the object to be located may be removably attached. The frame is connected at the end which is to extend into the interior of the trunk to a pair of chain-like track elements which are constructed of interconnected oppositely facing U-shaped channel links having engaging surfaces to limit the radius of curvature attainable by the chain in the direction extending upwardly from the trunk floor to a minimum radius and to limit the radius of curvature on the opposite side thereof to approximately a straight line. When an object is located in the trunk in a loaded position, the chain-like track elements lie flat on the floor of the trunk. To remove an object, the frame nearest the edge of the trunk is manually lifted up sufficiently to clear the trunk and then pulled horizontally out of the trunk. The chain-like track members roll up link by link and then straighten out to lift the opposite end of the frame upwardly out of the trunk. When the end of the frame to which the track elements are connected clears the edge of the trunk, the free end is manually lowered to the ground and the object carried by the frame may be removed from it. To load the trunk, the procedure is reversed.

Some prior art devices assist trunk loading/unloading by raising on demand the floor of the trunk up to the level of the back edge (lip) of the trunk. For example, U.S. Pat. No. 4,799,849 (Miller; 1989) discloses an automobile trunk loading and unloading device that uses a electric motorized winch operating on upstanding platform supports at the rear of the trunk. For example, U.S. Pat. No. 5,765,987 (Zimmermann; 1998) discloses an automobile trunk load and unload assist device and method that uses an electric air pump operating on vertically extensible pneumatic operators supporting a trunk bottom mounted platform.

Thus it is an object of the present invention to overcome the limitations of prior art devices in order to provide a compactly collapsible, portable and storable device that not only transports but also assists with lifting luggage both into and out of vehicles. A subsidiary object is that the invention will also assist with lifting luggage up to or down off other raised platforms typically utilized for luggage. It is a further object that the device is powered by an electric motor, thereby minimizing the effort required by a user.

### BRIEF SUMMARY OF THE INVENTION

According to the invention a loading and unloading device comprises: two parallel rails spaced apart at a bottom end by a ground resting foot, and at a top end by a handle; a carriage slidingly engaged with the rails; a cog rail parallel to the rails and fixed against movement relative to a portion of a rail; a motor drivingly connected between the carriage and the cog rail; and a double throw directional power switch controllably linked to the motor for selecting and controlling upward or downward motor driving of the carriage along the rails.

Further according to the invention, there are the following additional aspects and features:
two major embodiments of this invention are an independent rail lift device, and a suitcase rail lift device that is built into a suitcase such that the suitcase is the carriage
cog rail is attached to a slide rail (through the foot, on a side of a rail, inside a rail, etc.)
cog rail is a screw threaded rod and “nut” on rod is gear-toothed and held in a fork attached to carriage.
in the independent rail lift device embodiment: the carriage has a folding support plate hinged for folding between 0 and 90 degrees relative to long axis of rails at bottom and a two-part folding slide ramp at top that hingedly extends upward
a pivot notch (could be in either model) perpendicular to rails, opening laterally rearward from carriage
   positioned at the vertical center of gravity
directional power switch comprises a wireless remote control
   remote also operates security/identifying devices (id lite, beeper, alarm, lock)
directional power switch is a normally open, momentary action, double throw switch
   rocking pedal on the foot
rails telescope, and have a spring button position detent
   slot in outer rail+mating runner on inner rail slidingly fits in slot+roller in carriage to ride on rail/runner
handle comprises hook opening laterally rearward
hook at end of strap extends from the carriage
motor selectively winds/unwinds strap on a winch drum; selector switch linked to move motor to position for selected operation on winch or cog rail; directional power switch selects and initiates winding in or unwinding of strap
battery in device to power the motor
   rechargeable
   12V DC (for compatibility w/vehicle power)
cable and electrical connectors for external power supply (battery, car connection, wall-plug/converter)
foot retracts to allow wheel use

Other objects, features and advantages of the invention will become apparent in light of the following description thereof.

### BRIEF DESCRIPTION OF THE DRAWINGS

Reference will be made in detail to preferred embodiments of the invention, examples of which are illustrated in the accompanying drawing figures. The figures are intended to be illustrative, not limiting. Although the invention is generally described in the context of these preferred embodiments, it should be understood that it is not intended to limit the spirit and scope of the invention to these particular embodiments.

Certain elements in selected ones of the drawings may be illustrated not-to-scale, for illustrative clarity. The cross-sectional views, if any, presented herein may be in the form of “slices”, or “near-sighted” cross-sectional views, omitting certain background lines which would otherwise be visible in a true cross-sectional view, for illustrative clarity.

Elements of the figures can be numbered such that similar (including identical) elements may be referred to with similar numbers in a single drawing. For example, each of a plurality of elements collectively referred to as 199 may be referred to individually as 199a, 199b, 199c, etc. Or, related but modified elements may have the same number but are distinguished by primes. For example, 109, 109′, and 109″ are three different elements which are similar or related in some way, but have significant modifications, e.g., a tire 109 having a static imbalance versus a different tire 109′ of the same design, but having a couple imbalance. Such relationships, if any, between similar elements in the same or different figures will become apparent throughout the specification, including, if applicable, in the claims and abstract.

The structure, operation, and advantages of the present preferred embodiment of the invention will become further apparent upon consideration of the following description taken in conjunction with the accompanying drawings, wherein:

FIG. 1 is a perspective view of a loading and unloading device in a collapsed configuration, according to the invention;

FIGS. 2A-2B are front and side views, respectively, of the device of FIG. 1 in a collapsed configuration, according to the invention;

FIG. 3 is a perspective view of the device of FIG. 1 in an unfolded and extended configuration, according to the invention;

FIGS. 4A-4B are front and side views, respectively, of the device of FIG. 1 in an unfolded and extended configuration, according to the invention;

FIG. 4C is a partial front view of a bottom portion of an alternative embodiment of the device of FIG. 1 being modified to function as a dolly, according to the invention;

FIGS. 5A-5B are front and perspective views, respectively, of slide rails for the device of FIG. 1, according to the invention;

FIG. 6 is a side view of the slide rails of FIGS. 5A-5B with a carriage slidingly mounted on them plus a cutout view inside of a carriage housing, according to the invention;

FIG. 7A is a front view of components associated with the carriage housing of FIG. 6, the housing being shown for reference in ghost outline, according to the invention;

FIG. 7B is a top view of a wireless remote control for the device of FIG. 1, according to the invention;

FIG. 8A is a top view of a cogged slide rail for the device of FIG. 1, according to the invention;

FIG. 8B is a top view of a cog wheel for the device of FIG. 1, according to the invention;

FIG. 8C is a side view of the cog wheel of FIG. 8B operatively engaged with the cogged slide rail of FIG. 8A, according to the invention;

FIGS. 9A-9C are side views of stages in a loading operation using the device of FIG. 1, according to the invention;

FIGS. 10A-10C are side views of stages in an unloading operation using the device of FIG. 1, according to the invention;

FIGS. 11A-11B are back and front perspective views of a suitcase with a built-in embodiment of the device of FIG. 1, modified for such use according to the invention;

FIG. 12 is a back perspective view of the built-in device of FIGS. 11A-11B, partly extended, wherein a device cover is removed and a housing is cut away to show interior details, according to the invention; and

FIGS. 13A-13F are side views of stages in a loading operation using the built-in device of FIGS. 11A-12, according to the invention.

### DETAILED DESCRIPTION OF THE INVENTION

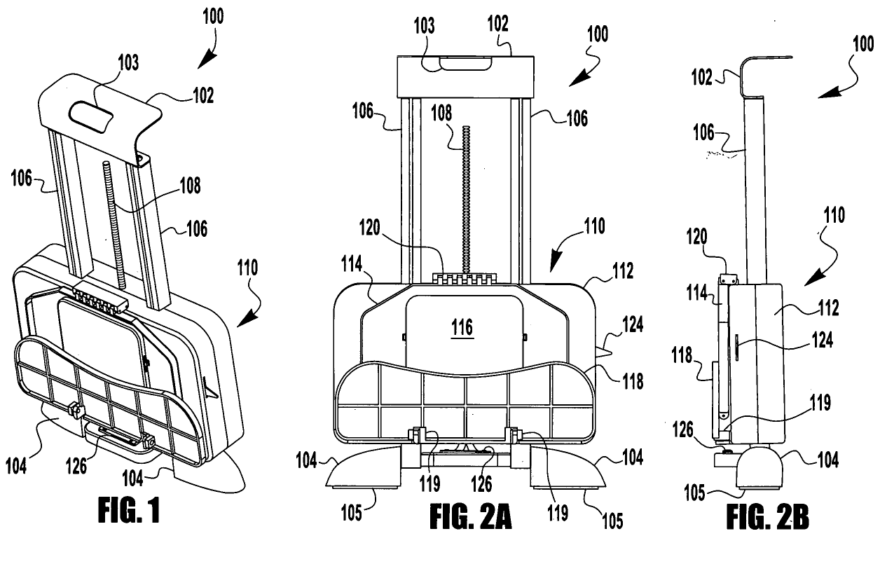

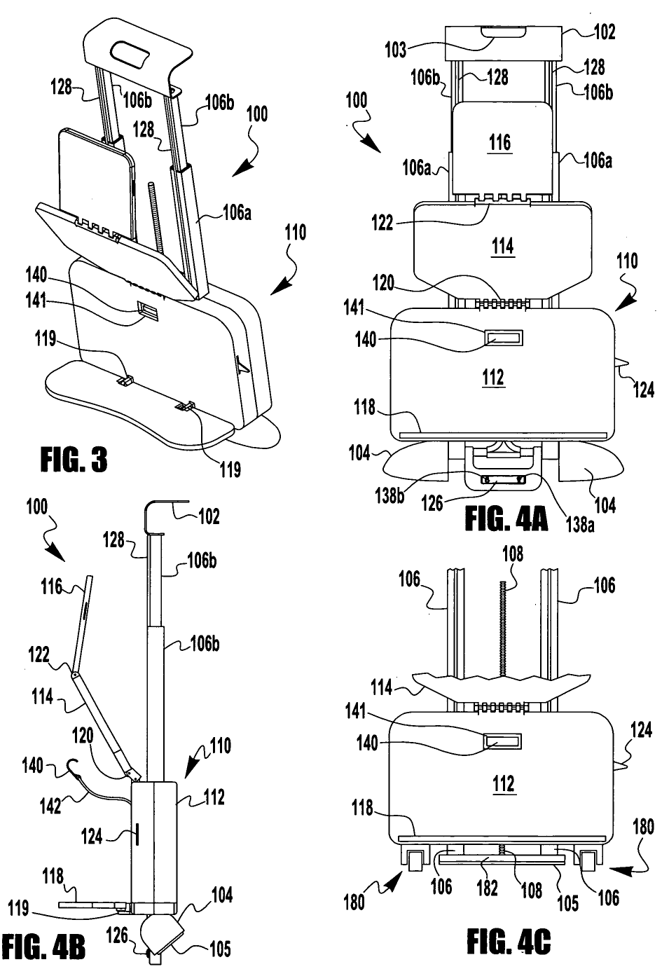

FIGS. 1 and 3 illustrate a rail lift embodiment 100 of a loading and unloading device according to the present invention, FIG. 1 showing it in a compact collapsed form that is readily handled or stored, and FIG. 3 showing it partially opened and extended for use in, for example, loading luggage and/or other items from vehicle luggage compartments (principally car/passenger vehicle trunks). The rail lift device 100 essentially comprises a collapsible ramp with a motorized carriage 110. Major components include two parallel telescoping slide rails 106 spaced apart at a bottom end by a ground resting foot 104, and at a top by a hook shaped handle 102; an acme screw threaded rod 108 parallel to the slide rails 106 and connected to the slide rails 106 via the foot 104; a motor driven carriage 110 slidingly engaged with the slide rails 106 and drivingly engaged with the screw rod 108; and a double throw directional power switch 126 controllably linked for selecting and initiating upward or downward powered movement of the carriage 110. As will become apparent from the disclosure hereinbelow, the threaded rod 108 is one possible form of what may be generically termed a “cog rail” along which a motor can drive the carriage 110 as a lift that slides on a ramp formed by leaning the slide rails 106 against a platform that is raised above the ground. In a preferred embodiment, the rail lift 100 is used to lift luggage up to, or down from, a platform that may be a passenger vehicle trunk, a bed, a luggage stand, a shelf, etc.

Referring now to FIGS. 1-4C, the handle 102 is shaped like a hook that opens rearward and has a handgrip hole 103 for convenience of carrying; and the foot 104 has a non-slip surface 105 (e.g., rubber) on a bottom ground-contacting portion of the foot 104. The carriage 110 comprises a housing 112 for containing drive components (described hereinbelow), a fold-out shelf 118, a strap hook 140 on a winching strap 142, and a foldably extending slide plate 114 and ramp plate 116. To enable compact folding, the back of the slide plate 114 is hollowed out to contain the ramp plate 116 when it is folded on a ramp hinge 122, and a double hinge 120 allows the slide plate 114 to fold down and lay flat on the front of the housing 112. The shelf 118 has a limit hinge 119 that prevents folding out the shelf 118 more than about ninety degrees, and the pivot point of the limit hinge 119 is offset forward so that the shelf 118 can fold up flat on top of the folded-down combined slide plate 114 and ramp plate 116. When not extended as shown in FIG. 4B, the strap 142 is winched into the housing 112 until the strap hook 140 is storably lodged in a suitable cavity 141. Although the strap hook 140 and strap 142 are shown emerging through a cavity 141 that is located on the top front face of the housing 112, it should be apparent that the cavity 141 could be located in any convenient spot on the housing 112. For example, the strap hook 140 may advantageously emerge from the bottom edge of the housing 112 such that the strap 142 could be wrapped outward and upward around the shelf 118 and an object resting on the shelf 118, thence to be hooked onto the object or onto the handle 102 (by hooking the strap hook 140 in the handgrip hole 103). In this way, the object (e.g., an item of luggage, a suitcase) can be secured to the carriage 110.

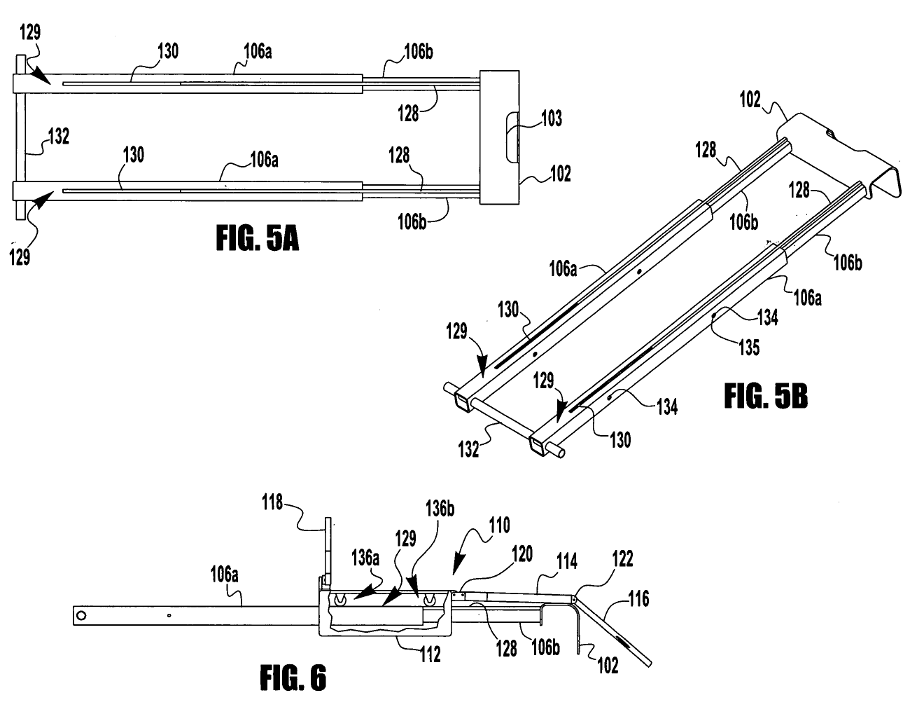

Referring now to FIGS. 5A-6, the slide rails 106 are telescoping and therefore comprise an outer rail 106a and an inner rail 106b. Detent holes 134 are provided in the outer rail 106a to detain the inner rail 106b at selected telescoping locations by using a mating spring loaded detent button 135. Preferably the selected locations are fully collapsed and fully extended (i.e., telescoped out to the longest extension that will support a rated load on the device—e.g., a 50% length increase). For example, in a preferred embodiment for use with personal luggage up to seventy pounds weight to be loaded into a passenger vehicle trunk, the slide rails 106 are telescoping square aluminum tubing, the collapsed length (from foot 104 to handle 102) is 24″ (inches), and the corresponding fully extended length is 36″ (optionally up to as much as 45″ depending upon the gauge and dimensions of the aluminum tubing). In another example, an embodiment for higher lifting such as for loading luggage into SUV trunks or personal pickup truck beds, has a collapsed length of 36″ and a corresponding fully extended length of 54″. In general, as much as is practical the inventive devices are made with lightweight, cost-effective materials of suitable strength such as plastic and aluminum. For example, the housing 112 and the slide plate 114, ramp plate 116, and shelf 118 are made with a suitable type of plastic.

The bottom ends of the slide rails 106 are attached to a foot pivot pin 132 upon which the foot 104 can be pivotingly mounted such that the non-slip surface 105 on the bottom of the foot 104 can rest flat on the ground when the rail lift device 100 is ramped at a suitable angle for lifting an object up to a platform. In order to allow the carriage 110 to slide upon both the outer slide rail 106a and the inner slide rail 106b, for example running on rollers 136 (bottom roller 136a and top roller 136b), a runner 128 is affixed to the upper surface of the inner slide rail 106b and a mating runner slot 130 is cut into an upper, running surface 129 of the outer slide rail 106a. For the purpose of telescoping, the runner 128 (preferably a plastic strip affixed on the inner slide rail 106b) slidingly fits in the runner slot 130; and the runner 128 is dimensioned such that the top surface of the runner 128 is level with the top surface of the outer slide rail 106a, thereby creating a level running surface 129 along the whole length of the slide rail 106 even when it is telescoped apart to a fully extended position. Finally, it may be noted from FIG. 6 that when the slide plate 114 is folded out along the slide rails 106, the double hinge 120 enables the slide plate 114 to lie flat in line with the outward surface of the housing 112. Furthermore, when the carriage 110 is driven far enough toward the handle 102, then the ramp hinge 122 allows the ramp plate 116 to fold back over the handle 102, thus providing a ramp surface for sliding an object over the handle onto or off of the carriage 110.

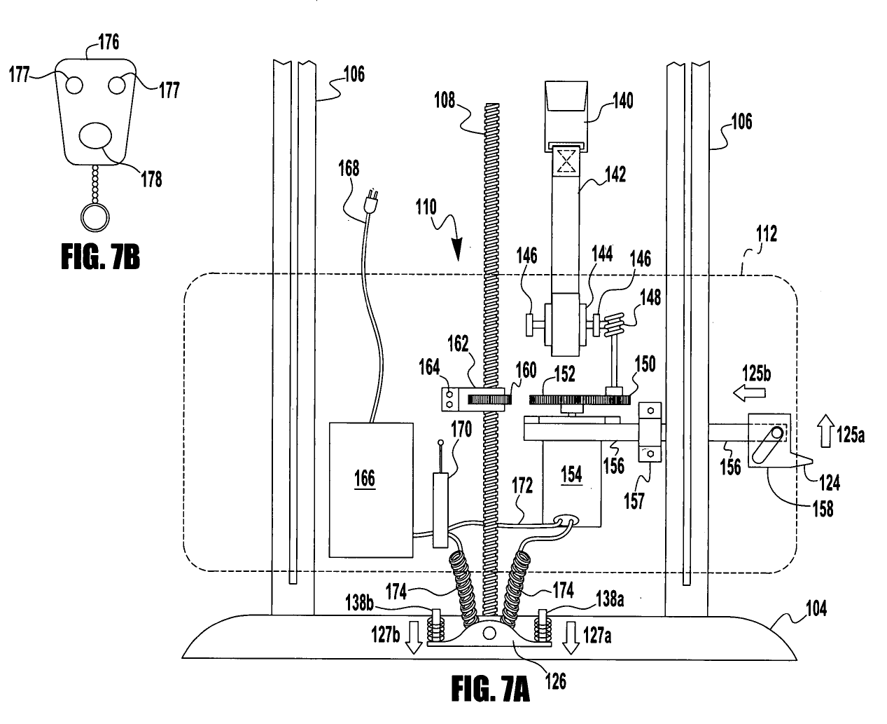

FIGS. 7A-7B schematically illustrate the major components of the drive system that is mainly housed in the housing 112 of the carriage 110. A portion of each slide rail passes through the housing 112 and is attached to the foot 104 (preferably pivotingly attached via the foot pivot pin 132). Likewise a portion of the threaded rod 108 passes through the housing 112 and is attached to the foot 104 (preferably pivotingly attached via the foot pivot pin 132). A twelve volt direct current (12V DC) motor 154 (e.g., a battery powered drill motor) is attached inside the housing 112 by a slide mount 157 slidingly holding a laterally sliding arm 156 that has a cam roller at an outside end, the cam roller interacting with a cam plate 158 that is connected to a selector switch 124 that protrudes from the side of the housing 112 (also see FIGS. 1-4C).

The winching strap 142 extends from the strap hook 140 through the housing 112 to be wound on a winch drum 144 that is mounted on the housing 112 by bearing blocks 146. A worm gear 148 operatively connects the winch drum through a shaft to a winch drive gear 150. When the motor 154 is positioned laterally to the right as shown, a main drive gear 152 of the motor 154 is drivingly engaged with the winch drive gear 150, thereby enabling the motor 154 to drive the winch drum 144 for winching in or unwinding the strap 142 depending upon the motor rotation direction as selected by the directional power switch 126. However, since it may not be desirable to unwind the strap 142 under power, the reverse operation of the motor 154 may be disabled, for example by a switch (not shown) that is operated by movement of the slide arm 156. Preferably such a switch would cause the motor 154 to rotate in a winching direction regardless of which direction is selected by the directional power switch 126 or other directional power controls (e.g., a wireless remote control 176). Also preferably, the winch drum is spring biased to maintain winching tension on the strap 142, against which the strap 142 may be manually pulled out of the housing 112 (like a seatbelt) when the motor's main drive gear 152 is not engaged with the winch drive gear 150.

On the threaded rod 108 (e.g., an acme screw rod) a lift drive gear 160 is screwingly mounted (e.g., by being threaded as an acme nut), and the lift drive gear 160 is rotatingly held by a bearing fork 162 that is attached (e.g., by bolts 164) to the housing 112. Thus, when the lift drive gear 160 is rotated, the resulting screw action will lift or lower the housing 112 (and thus the carriage 110) along the threaded rod 108 according to the direction of rotation of the lift drive gear 160. When an operator slides the selector switch 124 upward (direction 125a) the cam plate 158 causes the slide arm 156 to move the motor 154 laterally toward the lift drive gear 160 (direction 125b) to drivingly engage it with the main drive gear 152, thereby enabling the motor 154 to drive the lift drive gear 160 for lifting or lowering the housing 112 (and thus the carriage 110) along the threaded rod 108, depending upon the motor rotation direction as selected by the directional power switch 126.

The motor 154 is preferably powered by a rechargeable twelve volt battery 166, which can be charged through an external power cable 168 that can be connected to a vehicle power system by various known means including plugging into a cigarette lighter or into a socket that is installed in the trunk or on the back of the vehicle. The external power cable 168 could also be plugged into a household wall outlet via a suitable adapter/converter module. Alternatively, the external power cable 168 can be used to power the motor 154 independently of a stored energy source such as the battery 166. From a power source (i.e., the battery 166 and/or the external power cable 168), direct current is supplied to the directional power switch 126 through a cable 174 that is extensible if the directional power switch 126 is mounted as preferred on the foot 104. Similarly, under control of the directional power switch 126, DC current of a selected polarity is relayed from the directional power switch 126 to the motor 154 through another cable 174 that is extensible if the directional power switch 126 is mounted as preferred on the foot 104. The selection of polarity will determine the rotation direction of the motor 154, thereby selecting lifting or lowering action by the lift drive 160, 108 (i.e., the lift drive gear 160 operating on the threaded rod 108). Optionally a wireless receiver-controller 170 is operatively connected between the power source 166, 168 and the motor 154 (and the directional power switch 126, if present). A wireless remote control 176 has two directional control buttons 177, one for signaling the receiver-controller 170 to conduct DC current of a first polarity through the motor cable 172 to the motor 154, and the other for signaling the receiver-controller 170 to conduct DC current of a second, opposite polarity through the motor cable 172 to the motor 154, thereby selecting and controlling lifting or lowering action by the lift drive 160, 108. As discussed hereinabove, when a user has manually operated the selector switch 124 to select motorized operation of a winch drive 150, 148, 144 (i.e., the winch drive gear 150 operating on the winch drum 144 via the worm gear 148), it may not be desirable to unwind the strap 142 under power so the reverse operation of the motor 154 may be disabled, for example by a switch (not shown) that is operated by movement of the slide arm 156. Preferably such a switch would cause the motor 154 to rotate in a winching direction regardless of which direction is selected by the directional power switch 126 or the remote control directional power buttons 177. An optional button 178 on the remote control 176 may be used for miscellaneous added functions, for example it could lock/unlock operation of the motor 154.

Referring to FIG. 4A as well as FIG. 7A, the directional power switch 126 is a normally open, momentary action, double throw switch, for example, a center return two-way rocker switch having two spring biased pushbuttons 138. In another example, the directional power switch 126 is a side rocking foot pedal. For example, a right-hand pushbutton 138a selects lifting or upward action by the lift drive 160, 108 and controls the motor 154 to continue that action as long as the right-hand pushbutton 138a is depressed (e.g., by a user's foot). Similarly, a left-hand pushbutton 138b selects lowering or downward action by the lift drive 160, 108 and controls the motor 154 to continue that action as long as the left-hand pushbutton 138b is depressed (e.g., by a user's foot). The remote control directional power buttons 177 function in an equivalent way. Likewise, the pushbuttons 138 and directional power buttons 177 would cause continued operation of the winch drive 150, 148, 144 as long as they are depressed (preferably only causing winching in of the strap 142).

FIG. 4C illustrates a alternative embodiment of the rail lift device 100 wherein the foot 104 is changed to a smaller retractable foot 182 that leaves room for a pair of cart wheels 180 that protrude downward far enough that when the carriage 110 is lowered all the way down, then the retractable foot 182 is effectively retracted above the wheels 180 and prevented from contacting the ground. Thus the rail lift device 100 modified according to this embodiment can be used like a two wheeled dolly, similar to the arrangement of a suitcase having a pair of built-in wheels. Although modified somewhat in dimensions, the retractable foot 182 can still have all of the salient aspects of the regular foot 104. For example, the slide rails 106 and threaded rod 108 are still attached to it, and there is still a non-slip surface 105 below it. Of course other aspects not shown can still be implemented as well, e.g., a foot pivot pin 132, and a foot-mounted directional power switch 126.

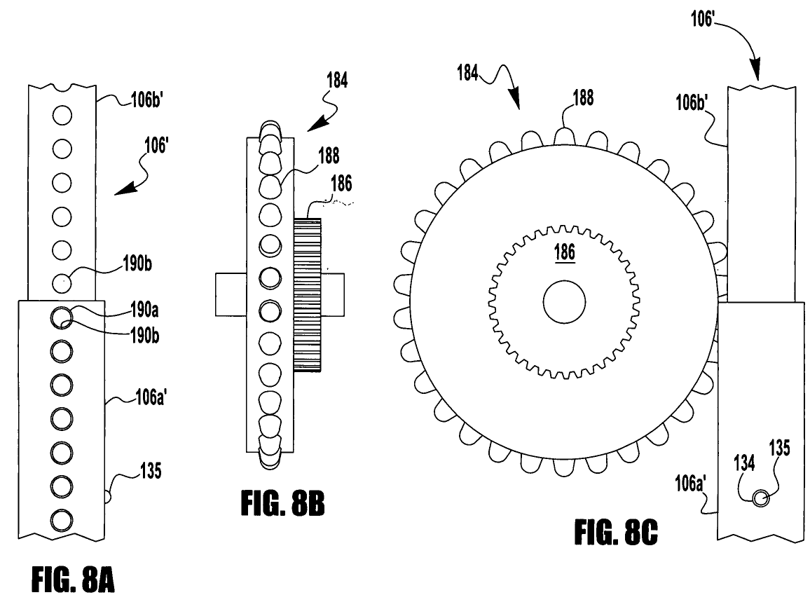

FIGS. 8A-8C illustrate another form of a lift drive that utilizes an alternate embodiment of a “cog rail” wherein a cogged slide rail 106′ has aligned cog holes 190 such that outer rail cog holes 190a passing through the outer cogged rail 106a′ have the same spacing as inner rail cog holes 190b that pass through the inner cogged rail 106b′, thereby allowing the inner and outer cog holes 190 to be aligned as shown whenever the cogged slide rail 106′ is telescoped to a suitable position. The suitable position can be defined by suitable positioning of the detent hole 134 and detent button 135. In order to more definitely hold the desired suitable position, the detent button 135 can be a straight-sided cylindrical latch pin instead of a rounded detent shape. A mating cogwheel 184 has cogs 188 protruding radially from its circumference and also has a cogwheel drive gear 186 (compare lift drive gear 160) for drivingly engaging with the main drive gear 152 of the motor 154. In the side view of FIG. 8C the cogwheel 184, which is attached to the housing (e.g., 112) by a bearing fork (not shown) is shown with the cogs 188 of the cogwheel 184 engaged with both outer rail cog holes 190a and inner rail cog holes 190b, even though the surface of the inner cogged rail 106b′ is not at the same level (i.e., same distance away) as the surface of the outer cogged rail 106a′. Thus the cogwheel 184 and cogged rail 106′ function like a rack and pinion drive with a variable length rack due to the telescoping nature of the cogged rail 106′. One difficulty of this embodiment is that a cog 188 can not be engaged in an inner rail cog hole 190b while the inner cogged rail 106b′ is being telescoped. Thus the cogwheel 184 must either be driven down to a lowest outer cog hole 190a or the cogwheel 184 must be disengaged by sliding it laterally away from the cogged rail 106′.

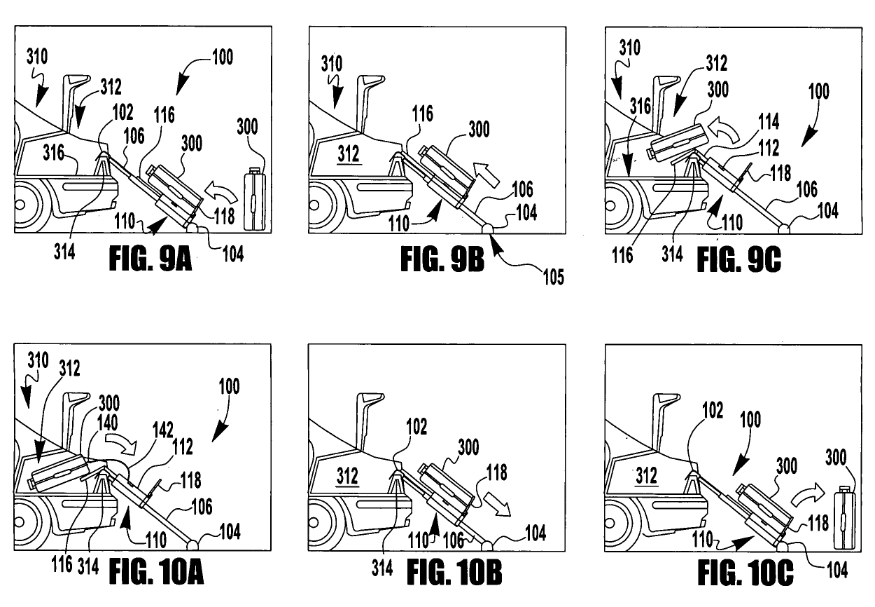

FIGS. 9A-9C show an operational example of the rail lift device 100 being used to load a suitcase 300 into the trunk 312 of a sedan style vehicle 310. In the initial stage illustrated by FIG. 9A, the device 100 has been removed from storage in the trunk 312, the shelf 118 opened out approximately perpendicular to the carriage 110, the slide rails 106 have been manually telescoped to a fully extended position (as indicated by detent button latching), and the plates including the uppermost ramp plate 116 have been unfolded and extended up along the slide rails 106. With the carriage 110 still lowered against the foot 104 as in the collapsed configuration, the hook shaped handle 102 has been hooked over a lip 314 of the trunk 312 that is elevated above a trunk floor 316, and the foot 104 is placed on the ground after pivoting it to face the non-slip bottom 105 against the ground. Finally the suitcase 300 is placed on the carriage 110 where it is supported by the shelf 118. Since the shelf 118 is hinged, rather than straight lifting of the suitcase 300, it can be dragged up the ramped device 100 over a folded flat shelf 118 and up far enough on the carriage 110 that the shelf 118 can be folded down for support. Alternatively, the suitcase 300 can be slid sideways onto the carriage 110 and opened shelf 118. Furthermore, the rail lift device 100 can be tilted up such that the shelf 118 is angled down to the ground; the suitcase 300 is dragged onto the shelf 118, and the device 100 is tilted back against the vehicle 310. This last option is made especially easy if the retractable foot 182 embodiment of the device 100 is being used, wherein the shelf 118 can be laid flat on the ground like the shelf of a dolly.

In the lifting stage illustrated by FIG. 9B, the motorized lift drivel 60, 108 within the carriage 110 is lifting the suitcase 300 along the ramped slide rails 106 up toward the trunk 312.

In the final loading stage illustrated by FIG. 9C, the carriage 110 has stopped after being motor driven up as high as it can go, and the ramp plate 116 has folded over the trunk lip 314, thereby providing a convenient ramp from the trunk lip 314 down into the trunk 312. The suitcase 300, having been placed on the carriage with its long axis pointed upward, has been lifted up enough that the suitcase 300 extends above the trunk lip 314. Thus it is a relatively easy matter for the user to topple the suitcase over the trunk lip 314 and to push it down the ramp plate 116 to the trunk floor 316. Alternatively, especially for heavy and/or relative short objects, the suitcase 300 can be toppled and caused to slide into the trunk 312 by raising the foot 104 of the rail lift device 100 so that the handle 102 forms a pivot for advantageous lever action by the extended slide rails 106. Once loading of the luggage 300 has been completed, the carriage 110 can be motor driven back down to the foot 104, whereupon the device 100 can be manually collapsed and folded into a compact arrangement (as in FIG. 1) for storage or transport as desired.

FIGS. 10A-10C show an operational example of the rail lift device 100 being used to unload a suitcase 300 from the floor 316 of a trunk 312 of a sedan style vehicle 310 that has a raised trunk lip 314. In the initial stage illustrated by FIG. 10A, the rail lift device 100 has been placed in the configuration accomplished by the suitcase loading steps described hereinabove for FIGS. 9A-9C (without using a suitcase 300). In addition, the strap 142 has been pulled out of the carriage 110 until the strap hook 140 can be hooked onto the suitcase 300, preferably close to the outward (trunk lip 314 facing) end of the suitcase 300, for example hooked on a suitcase handle. Then the winch drive 150, 148, 144 is selected activated for winching in the strap 142, thereby hauling the suitcase 300 up the ramp plate 116, over the handle 102 and trunk lip 314, and down onto the carriage 110 and shelf 118. Depending upon the suitcase weight, trunk depth, and location of the strap hook 140 on the suitcase 300, the user may need to provide a bit of assistance to get the suitcase 300 properly positioned for sliding up the ramp plate 116, or for sliding over the apex of the trunk lip 314. It may also be advantageous to stand on the foot 104 to keep it on the ground.

In the lowering stage illustrated by FIG. 10B, the motorized lift drive 160, 108 within the carriage 110 is lowering the suitcase 300 along the ramped slide rails 106 down toward the foot 104 on the ground.

In the final unloading stage illustrated by FIG. 10C, the carriage 110 has stopped after being motor driven down as low as it can go. Then the user will remove the suitcase 300 from the carriage 110, by tilting and lifting if not too heavy, otherwise by sliding it sideways off the carriage 110 and shelf 118, or by lifting the device handle 102 to tilt the rail lift device 100 up until the suitcase topples or slides off the shelf 118, again taking advantage of the lever action provided by the extended slide rails 106 (now pivoting on the foot 104). Once unloading of the luggage 300 has been completed, the luggage 300 can be rolled away or otherwise transported, and the device 100 can be manually collapsed and folded into a compact arrangement (as in FIG. 1) for storage or transport as desired. If the retractable foot 182 embodiment of the device 100 is being used, then tilting up the device 100 will enable the shelf 118 to be laid flat on the ground for unloading like the shelf of a dolly, and furthermore, the device 100 can be used like a dolly to conveniently and easily transport the unloaded suitcase 300.

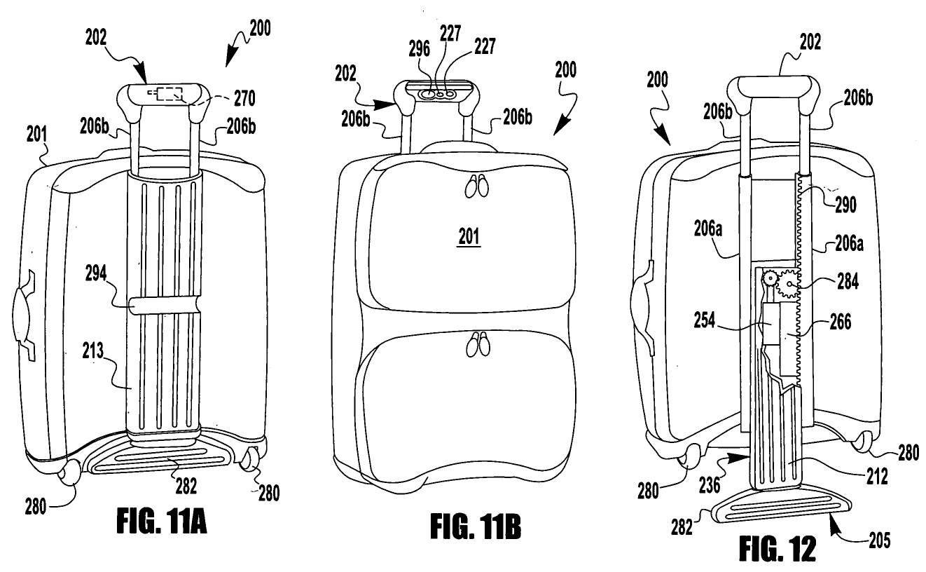

Referring now to FIGS. 11A-12, a piece of luggage like a suitcase 201 has been modified to build in a rail lift device like the device 100 described hereinabove, especially the one having a retractable foot 182. A rail lift suitcase 200 comprises a suitcase 201 of arbitrary design plus built-in components of a rail lift device (e.g., device 100) including a pair of telescoping rails 206 spaced apart by a handle 202 at the top and by a ground resting retractable foot 282, the spacing being held by affixing an outer rail 206b portion of both rails 206 to the suitcase 201 where the lifting device 100 is built-in to the suitcase 201. An inner rail 206b telescopes within the outer rail 206a, and a top end of the inner rail 206b is where the rail 206 is attached to the handle 202. The handle 202 angles rearward (compare the hook shaped handle 102). A device cover 213 is affixed on the back of the suitcase 201 to cover the workings of the built-in rail lift device 100. A pivot groove 294, opening rearward, crosses the back of the device cover 213 at the approximate center of gravity of the rail lift suitcase 200. The suitcase 201 has cart wheels 280 (compare 180) that protrude down below the retractable foot 282 which has a non-slip surface 205 (compare 105) on its bottom.

Referring particularly to the cutaway view of FIG. 12 with the device cover 213 also removed, a housing 212 (compare 112) encloses motorized drive components including a twelve volt DC lift motor 254 and a suitable twelve volt battery 266, preferably rechargeable (electrical cable and connections not shown). Analogously to the rollers 136 used to slide along the rails 206, the suitcase rail lift device 200 has rail grooves 236 formed in the rail-facing sides of the housing 212. Preferably a form of a lift drive is used that utilizes another alternate embodiment of a “cog rail” wherein rack teeth 290 (compare cog holes 190) extend inward from the outer slide rail 206a which extends substantially to the top of the suitcase 201. (The rail groove 236 straddles the rack teeth 290.) A mating pinion gear 284 (compare cog wheel 184) drivingly engages with the rack teeth 290 and in turn is geared to be driven by the motor 254.

Controls for the drive are preferably built into the handle 202 and include directional power buttons 227 (compare 177) and an optional wireless receiver-controller 270 (compare 170) that can work with a wireless remote control 176. Optionally a bag locator 296 being an LED and/or an audible device is/are built into the handle 202 or otherwise located on the rail lift suitcase 200. The locator can be activated by pressing the extra button 178 on the wireless remote control 176. When activated, the locator 296 will flashing a light and/or make a sound that will help to distinguish the user's bag from other look-alikes in a baggage claim area. The locator 296 can also function as a power-on indicator and/or as a security alarm.

By comparing the suitcase rail lift device 200 to the rail lift device 100 loaded with a suitcase 300, it can be seen that the suitcase rail lift device 200 uses the suitcase 201 as a carriage 112, and this “suitcase-carriage” 201 does not slide on the rails 206 but is instead fixedly attached to the outer rails 206a. The drive motor 254 in its housing 212 is not attached to the “suitcase-carriage” 201 but is instead attached to the foot 282 while the rails 206 and the cog rail 290 are attached to the “suitcase-carriage” 201 instead of the foot 282, thereby reversing the operation of the suitcase rail lift device 200 compared to the rail lift device 100. Driven by the motor 254 the rails 206 are lifted away from the motor 254, sliding along the housing 212 via the rail grooves 236; whereas, driven by the motor 154, the housing 112 which is part of the carriage 110 is lifted along with the motor 154, sliding along the rails 206 via the rollers 136.

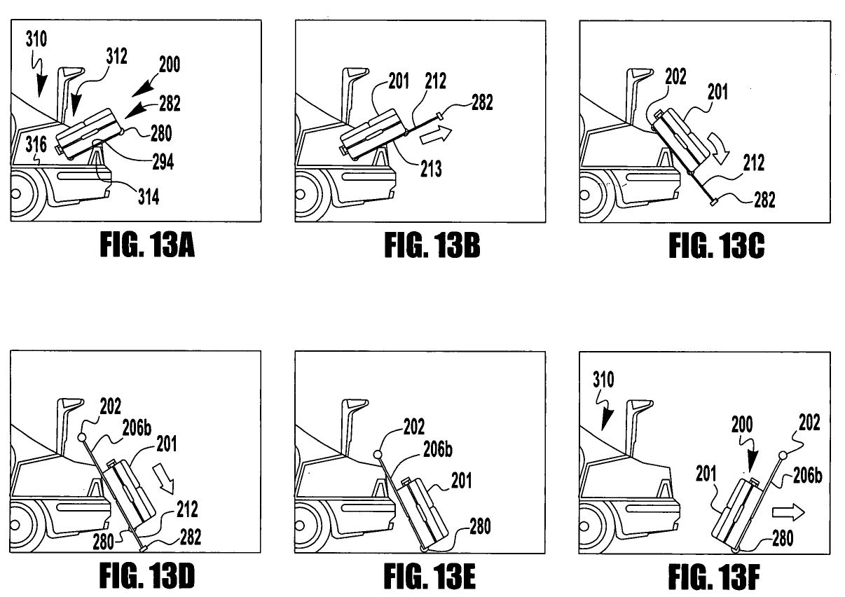

FIGS. 13A-13F show an operational example of the rail lift suitcase 200 being used to unload itself from the floor 316 of a trunk 312 of a sedan style vehicle 310 that has a raised trunk lip 314. In the initial stage illustrated by FIG. 10A, the rail lift suitcase 200 has been pulled out of the trunk 312 far enough to hook the pivot notch 294 on the trunk lip 314. (This is simplified when a flat-floored, no trunk lip 314, truck bed or SUV/van/wagon is being unloaded and the suitcase 200 is simply dragged until the pivot notch 294 is hooked on the outer edge of the trunk floor 316.) In the next stage shown in FIG. 13B, the motor 254 is activated to extend the retractable foot 282 outward a sufficient distance while balancing the suitcase 201. Alternatively, the foot 282 can be extended before the suitcase 201 is balanced at the tipping point. In the next stage shown in FIG. 13C, the foot 282 has been fully extended and the suitcase is tilted downward toward the ground. The extended housing 212 provides good leverage for controlling the tipping of a heavy suitcase 201. In the next stage shown in FIGS. 13D-13E, the retractable foot 282 has been tilted down to rest on the ground, and the pivot notch 294 has been unhooked from the trunk lip 314 (possibly needing a bit of manual assistance) and the rail lift suitcase 200 is being lowered by the lift drive 254, 284 which is retracting the retractable foot 282, thereby shortening the amount of housing 212 which extends between the suitcase 201 and the foot 282. The device cover 213 is made from a relatively rigid material that is also relatively slippery and non-scratching of whatever it slides on, therefore as the rail lift suitcase 200 is lowered its device cover 213 slides against the trunk lip 314. At any time before the top edge of the device cover 213 slides down below the trunk lip 314 the handle 202 is pulled upward, extendingly telescoping the inner rails 206b so that the suitcase 201 can continue being powered downward while the inner rails 206b slide against the trunk lip 314. Alternatively the handle 202 can hook on the trunk lip 314, preferably assisted by pressure from the user, and then the motor 254 will pull against the hooked handle 202, thereby extending the inner rails 206b as the motor 254 retracts the retractable foot 282 while driving the suitcase 201 downward toward the ground. This may be desirable since it reduces sliding of the rail lift suitcase 200 against the trunk lip 314. As illustrated in FIGS. 13E-13F, once the suitcase 201 reaches the ground, further retraction of the retractable foot 282 will remove it from ground contact and the rail lift suitcase 200 will be resting on its cart wheels 280, ready to be pulled by the handle 202 so that the suitcase 201 can be transported as desired. The inner telescoping rails 206b can be left extended for towing the rolling suitcase 201 away, or they can be pushed to telescope inward for stowage of the rails 206 within the body of the rail lift suitcase 200. If the inner rails 206b had only been extended by hooking the handle 202 on the trunk lip 314, then the rails 206 may not have been extended enough to either place them in a detented position or at a length that is convenient for the user who will be pulling the rail lift suitcase 200. In either case, the user may want to adjust the extension length of the rails 206 by manually telescoping them inward or outward.

The process described hereinabove is reversed for loading the rail lift suitcase 200 into the trunk 312 of a vehicle 310. As illustrated in FIG. 13F, the user transports the rail lift suitcase 200 to the vehicle trunk 312 by pulling on the handle 202 so that the suitcase 201 follows the user rolling on its cart wheels 180 like a rolling suitcase. The retractable foot 282 is fully retracted to avoid interference with the rolling transport and the telescoping inner rails 206b are extended to a length selected by the user as being convenient for the transporting operation. Of course the handle 202 and inner rails 206b can be pushed in for stowing and the rail lift suitcase 200 can be transported like o normal suitcase. As illustrated in FIG. 13E, the user manually extends the telescoping inner rails 206b as needed to a length adjusted to the trunk lip 314 (or wagon trunk floor 316) height and leans the handle 202 and inner rails 206b against the trunk lip 314, thereby forming a ramp. Then, as illustrated in FIG. 13D, the motor 254 is activated in the lifting direction (e.g., by pressing and holding the appropriate directional power button 177 on the wireless remote control 176). As the suitcase 201 rises up the ramp being pushed by the motorized extension of the retractable foot 282 and the housing 212, the foot 282 with its non-slip bottom 205 remains in contact with the ground, preventing sliding away from the vehicle 310. As shown in FIG. 13C, once the top of the device cover 213 is pushed up over the trunk lip 314 then the inner rails 206b can be manually telescoped inward to retract the handle 202 to the top of the suitcase 221. Then when the pivot notch 294 slides over and hooks on the trunk lip 314, the motor 254 is stopped and the center of balance shifts such that the rail lift suitcase 200 can be easily pivoted on the pivot notch 294 to tilt the suitcase 201 down into the trunk 312. As shown in FIG. 13B, the retractable foot 282 and housing 212 can now be retracted out of the way into the device cover 213. Finally, as shown in FIG. 13A, the rail lift suitcase 200 is resting on the trunk lip 314 on its pivot notch 294. The user then lifts the suitcase 201 enough to unhook the pivot notch 294 and slides the rail lift suitcase 200 the rest of the way into the vehicle trunk 312 to rest on the trunk floor 316.

It can be seen that other operating sequences may be used given the disclosed rail lift device 100 or the rail lift suitcase 200. For example, the retractable foot 282 may not be retracted until after the rail lift suitcase 200 is manually tilted and even partly slid into the trunk 312 because the suitcase 201 may be loaded such that it is heavier below the pivot notch 294. Any such variations of the operating sequences disclosed herein should be considered within the scope of the present invention.

Although the invention has been illustrated and described in detail in the drawings and foregoing description, the same is to be considered as illustrative and not restrictive in character—it being understood that only preferred embodiments have been shown and described, and that all changes and modifications that come within the spirit of the invention are desired to be protected. Undoubtedly, many other “variations” on the “themes” set forth hereinabove will occur to one having ordinary skill in the art to which the present invention most nearly pertains, and such variations are intended to be within the scope of the invention, as disclosed herein.

What is claimed is:

1. A loading and unloading device comprising:
two parallel rails spaced apart at a bottom end by a ground resting foot, and at a top end by a handle;
a carriage slidingly engaged with the rails;
a cog rail parallel to the rails and fixed against movement relative to a portion of a rail;
a motor drivingly connected between the carriage and the cog rail; and
a double throw directional power switch controllably linked to the motor for selecting and controlling upward or downward motor driving of the carriage along the rails.
